(19) United States
(12) Patent Application Publication
(10) Pub. No.: US 2026/0260670 A1
(43) Pub. Date: Sep. 3, 2026

(54) MEMORY, MEMORY SYSTEMS AND METHODS FOR FORMING MEMORY

(71) Applicant: Yangtze Memory Technologies Co., Ltd., Wuhan (CN)

(72) Inventors: Danyang Li, Wuhan (CN); Yu Wang, Wuhan (CN); Xu Hou, Wuhan (CN)

(21) Appl. No.: 19/337,795

(22) Filed: Sep. 23, 2025

(30) Foreign Application Priority Data
Mar. 3, 2025 (CN) 202510245049.1

(51) Int. Cl. G11C 5/06; G11C 5/02; G11C 11/408; G11C 11/4091; H10B 12/00

(52) U.S. Cl. CPC G11C 5/063; G11C 5/025; G11C 11/4085; G11C 11/4091; H10B 12/09; H10B 12/50

(57) ABSTRACT

This application discloses a memory, a memory system and a method for forming the memory and belongs to the field of memory technology. According to the memory, by disposing a first connection line between the memory banks of a memory array and not disposing the first connection line within the memory bank, the memory banks are enabled to accommodate more memory blocks or memory blocks with larger size, thereby increasing the storage capacity of a single memory bank without changing the size of the memory bank, and thus increasing the storage capacity of the memory without changing the size of the memory.

### CROSS-REFERENCE TO RELATED APPLICATIONS

This application claims priority to and the benefit of Chinese Patent Application 202510245049.1, filed on March 3, 2025, which is hereby incorporated by reference in its entirety.

### TECHNICAL FIELD

This application relates to the field of memory technology, and in particular, to memory, memory systems, and methods for forming the memory.

### BACKGROUND

A memory in a three-dimensional (3D) architecture may include a memory array and a peripheral circuit, wherein the memory array is configured to store data, and the peripheral circuit may control the memory array, so that the memory array performs operations such as reading data, writing data, or refreshing data.

### BRIEF DESCRIPTION OF THE DRAWINGS

FIG. 1 is a schematic diagram of an application environment of a memory system according to an example implementation;

FIG. 2 is a schematic diagram of a memory card according to an example implementation;

FIG. 3 is a schematic diagram of a solid state drive according to an example implementation;

FIG. 4 is a schematic diagram of a cross section of a memory according to an example implementation;

FIG. 5 is a cross-sectional view and top view of a memory device according to an example implementation;

FIG. 6 is a block diagram of a memory according to an example implementation;

FIG. 7 is a schematic diagram of a view of a memory in a direction perpendicular to a stacking direction according to an example implementation;

FIG. 8 is a schematic diagram of a view of another memory in a direction perpendicular to a stacking direction according to an example implementation;

FIG. 9 is a schematic diagram of a view of another memory in a direction perpendicular to a stacking direction according to an example implementation;

FIG. 10 is a schematic diagram of a view of another memory in a direction perpendicular to a stacking direction according to an example implementation;

FIG. 11 is a schematic diagram of distribution of a target connection line outside a memory bank according to an example implementation;

FIG. 12 is a schematic diagram of distribution of first connection lines between adjacent memory banks according to an example implementation;

FIG. 13 is a schematic diagram of another distribution of first connection lines between adjacent memory banks according to an example implementation;

FIG. 14 is a schematic diagram of another distribution of first connection lines between adjacent memory banks according to an example implementation;

FIG. 15 is a schematic diagram of another distribution of first connection lines between adjacent memory banks according to an example implementation; and

FIG. 16 is a flowchart of a method for forming a memory according to an example implementation.

### DETAILED DESCRIPTION

To make the objectives, technical solutions, and advantages of this application clearer, implementations of this application will be further described in detail with reference to the accompanying drawings in the following.

In this application, terms such as “first” and “second” are used to distinguish between same items or similar items with substantially the same functions and functions, and it should be understood that “first”, “second”, and “n-th” do not have a logical or sequential dependency relationship, or do not define a quantity and an execution sequence. It should also be understood that although the following description uses the terms such as first, second, etc. to describe various elements, these elements should not be limited by the terms.

These terms are used only to distinguish one element from another. For example, a first element can be referred to as a second element, and similarly, a second element can also be referred to as a first element, without departing from the scope of the various examples. The first element and the second element may both be elements, and in some cases, may be separate and distinct elements.

“At least one” refers to “one or more”, for example, at least one element may be any integer number of elements greater than or equal to one, such as one element, two elements, or three elements. While “at least two” refers to “two or more”, for example, at least two elements may be any integer number of elements greater than or equal to two, such as two elements, three elements.

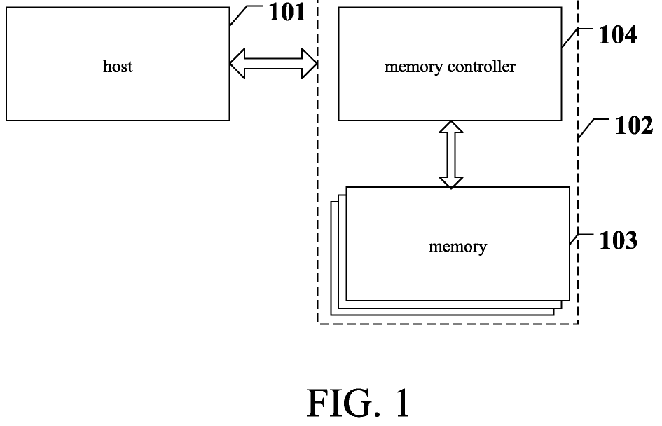

This application relates to a memory system. FIG. 1 is a schematic diagram of an application environment of a memory system according to an example implementation, and as shown in FIG. 1, the application environment includes a host 101 and a memory system 102, wherein the host 101 may be a mobile phone, a desktop computer, a laptop computer, a tablet computer, a vehicle computer, a game console, a printer, a positioning device, a wearable electronic device, an intelligent sensor, a virtual reality (VR) device, an augmented reality (AR) device, or any other suitable electronic device having storage therein. Depending on the interface protocol between the memory system 102 and the host 101, the memory system 102 may be configured as, for example, a universal flash storage (UFS) device, a solid state drive (SSD), a multimedia card (MMC) (such as an embedded multimedia card (eMMC), a small size multimedia card (RS-MMC), and a micro MMC, etc.), a secure digital (SD) card (such as a mini SD and a micro SD), a computer memory card international association (PCMCIA) card type of memory device, a peripheral component interconnect (PCI) type of memory device, a PCI express (PCI-E) type of memory device, a compact flash (CF) card, a smart media card, or a memory stick, etc.

The host 101 may control operations of the memory system 102, for example, the host 101 may control operations of the memory system 102 through an instruction, for example, the host 101 sends an instruction to the memory system 102, and the memory controller 104 performs a corresponding operation (such as an operation of data programming, data reading, data erasing, or other operations) in response to the instruction of the host 101. The memory system 102 may store data accessed by the host 101, the host 101 may be configured to send data to the memory system 102, and the data will be stored by the memory system 102. Alternatively, the host 101 may be configured to receive data from the memory system 102.

As shown in FIG. 1, the memory system 102 includes at least one memory 103 and a memory controller 104, wherein the memory 103 is a storage medium configured to store data in the memory system 102, such as a NAND flash memory device, a three-dimensional (3D) NAND flash memory device, or the like.

According to some implementations, the memory controller 104 is coupled to the host 101 and the memory 103, and is configured to control the memory 103.

In some implementations, the memory controller 104 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc.

In some implementations, the memory controller 104 is designed for operating in a high duty-cycle environment solid state drive (SSD) or embedded multi-media-card (eMMC) used as data storage for mobile devices, such as smartphones, tablet computers, laptop computers, etc., and enterprise storage arrays.

The memory controller 104 may be configured to control operations of the memory 103, such as read, erase, and program operations. The memory controller 104 may also be configured to manage various functions regarding data stored or to be stored in the memory 103, including but not limited to bad block management, garbage collection, logical-to-physical address translation, wear leveling, and the like. In some implementations, the memory controller 104 is further configured to process error correction codes (ECCs) with respect to data read from or written to the memory 103.

Memory controller 104 may also perform any other suitable functions, such as formatting the memory 103. Memory controller 104 may communicate with an external device (e.g., host 101) according to a particular communication protocol. For example, the memory controller 104 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller 104 and the one or more memories 103 may be integrated into various types of storage devices, for example, included in the same package (e.g., Universal Flash Storage (UFS) package or eMMC package). That is, the application environment may be implemented and packaged into different types of end electronic products.

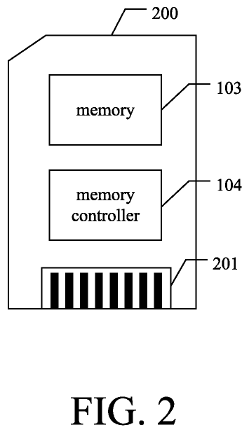

FIG. 2 is a schematic diagram of a memory card according to an example implementation, and as shown in FIG. 2, a memory controller 104 and a single memory 103 may be integrated into a memory card 200. The memory card 200 may include a PC card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), a UFS, or the like. The memory card 200 may also include a memory card connector 201 that couples the memory card 200 with a host (e.g., the host 101 in FIG. 1).

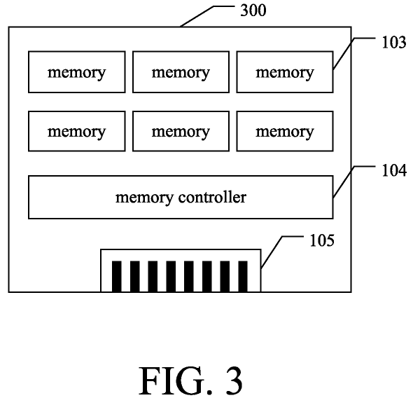

FIG. 3 is a schematic diagram of a solid-state drive according to an example implementation, as shown in FIG. 3, the memory controller 104 and a plurality of memories 103 may be integrated into a solid-state drive (SSD) 300. The SSD 300 may also include an SSD connector 105 that couples the SSD 300 with a host (e.g., the host 101 in FIG. 1). In some implementations, at least one of the storage capacity or the operation speed of the SSD 300 is greater than at least one of the storage capacity or the operation speed of the memory card 200.

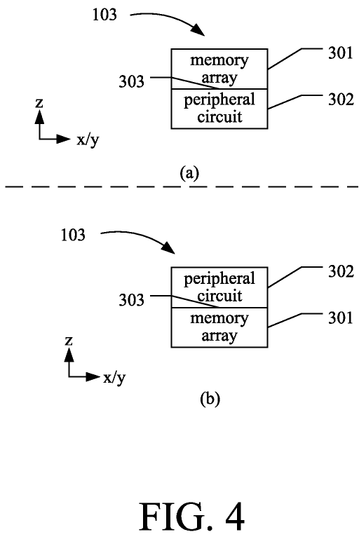

The foregoing describes an application environment of the memory 103, and the following will describe a structure of the memory 103 in detail with reference to FIG. 4.

FIG. 4 is a schematic diagram of a cross section of a memory according to an example implementation, as shown in (a) and (b) of FIG. 4, the memory 103 includes at least one memory array 301 and a peripheral circuit 302, wherein the memory array 301 is configured to store data, and the peripheral circuit 302 is configured to control the memory array 301.

The peripheral circuit 302 and the memory array 301 are stacked. The stacking arrangement can be implemented by bonding, for example, the memory array 301 and the peripheral circuit 302 are bonded to form a bonded chip. As shown in (a) and (b) of FIG. 4, the memory 103 further includes a bonding interface 303 perpendicular to the memory array 301 and the peripheral circuit 302 and located between the memory array 301 and the peripheral circuit 302. The memory array 301 and the peripheral circuit 302 form interconnects (for example, bonding contacts) through the bonding interface 303, so as to form a direct short-distance (for example, micron level) electrical connection between the memory array 301 and the peripheral circuit 302 instead of a long-distance (for example, millimeter or centimeter level) chip-to-chip data bus connection on a circuit board (for example, a printed circuit board (PCB)), thereby eliminating chip interface latency and achieving high-speed input-output (I/O) throughput with reduced power consumption.

The bonding interface 303 is formed vertically between the memory array 301 and the peripheral circuit 302, and the memory array 301 and the peripheral circuit 302 are vertically connected by bonding (e.g., hybrid bonding). Hybrid bonding, also referred to as “metal/dielectric hybrid bonding”, is a direct bonding technique (e.g., forming a bond between surfaces without using an intermediate layer (e.g., solder or adhesive)) and can achieve both metal-metal (e.g., copper to copper) bonding and dielectric-dielectric (e.g., silicon oxide-silicon oxide) bonding simultaneously. Data/signal transmission between the memory array 301 and the peripheral circuit 302 may be performed through interconnects (e.g., bonding contacts) across the bonding interface 303.

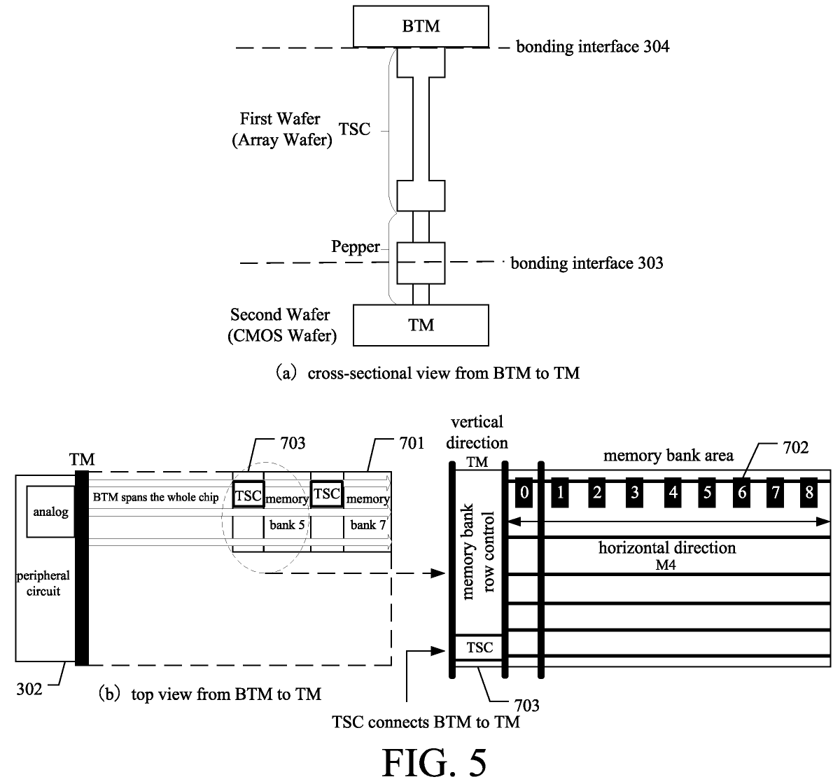

For example, the memory array 301 and the peripheral circuit 302 may be formed on different wafers and bonded together in a face-to-face manner through the bonding interface 303. As shown in the cross-sectional view of the memory 103 shown in (a) of FIG. 5, the memory 103 includes a first wafer and a second wafer, a memory array 301 (not shown in (a) of FIG. 5) is formed on the first wafer which may also be referred to as an array wafer, and a peripheral circuit 302 is formed on the second wafer which may also be referred to as a complementary metal oxide semiconductor wafer(CMOS Wafer), and the first wafer and the second wafer may form a large number of interconnects through the bonding interface 303 to make a direct, short-distance (e.g., micron level) electrical connection between the memory array 301 and the peripheral circuit 302. During the back end of line (BEOL) process of the memory array 301 and the peripheral circuit 302, interconnects may be formed on the bonding interface 303 to bond the two wafers together.

In some implementations, the memory array 301 and the peripheral circuit 302 may be formed on different substrates, for example, the first wafer includes a first substrate, the second wafer includes a second substrate, the memory array 301 is formed on the first substrate, and the peripheral circuit 302 is formed on the second substrate. Of course, the memory array 301 and the peripheral circuit 302 may not be formed on the substrate, and in this case, the first wafer may not include the first substrate, and the second wafer may not include the second substrate. Here, implementations of this application do not limit whether the memory array 301 and the peripheral circuit 302 are formed on the substrate.

For the relative position between the memory array 301 and the peripheral circuit 302, as shown in (a) of FIG. 4, in a stacking direction of the memory array 301 and the peripheral circuit 302 (for example, z-axis), the memory array 301 is disposed above the peripheral circuit 302. Alternatively, as shown in (b) of FIG. 4, in the stacking direction of the memory array 301 and the peripheral circuit 302 (for example, z-axis), the peripheral circuit 302 is disposed above the memory array 301. It should be understood that, as shown in (a) and (b) of FIG. 4, an x-axis, a y-axis, and a z-axis are included, to further illustrate a spatial relationship between components in the memory 103. The x-y plane may be the top surface of the front side of the wafer in the memory 103, the memory array 301 may be formed on the top surface of the first wafer along the x-y plane, and the peripheral circuit 302 may be formed on the top surface of the second wafer along the x-y plane. The stacking direction in the present application refers to a direction in which the memory array 301 and the peripheral circuit 302 are stacked, the z-axis is perpendicular to the x-axis and the y-axis and is the stacking direction in which it is determined whether one component (such as the memory array 301) in the memory is “on”, “above” or “below” another component (such as the peripheral circuit 302). The same concept for describing spatial relationships is applied in this application.

With respect to the arrangement of the memory array and the peripheral circuit being in the same plane, the size of the memory can be reduced by stacking the memory array 301 and the peripheral circuit 302. A plurality of memory arrays are stacked on top of each other using bonding techniques, enabling more memory arrays to be disposed in the limited size of the memory to increase the storage capacity of the memory.

The foregoing describes the stacking manner of the memory array 301 and the peripheral circuit 302, and the following will describe internal structures of the memory array 301 and the peripheral circuit 302.

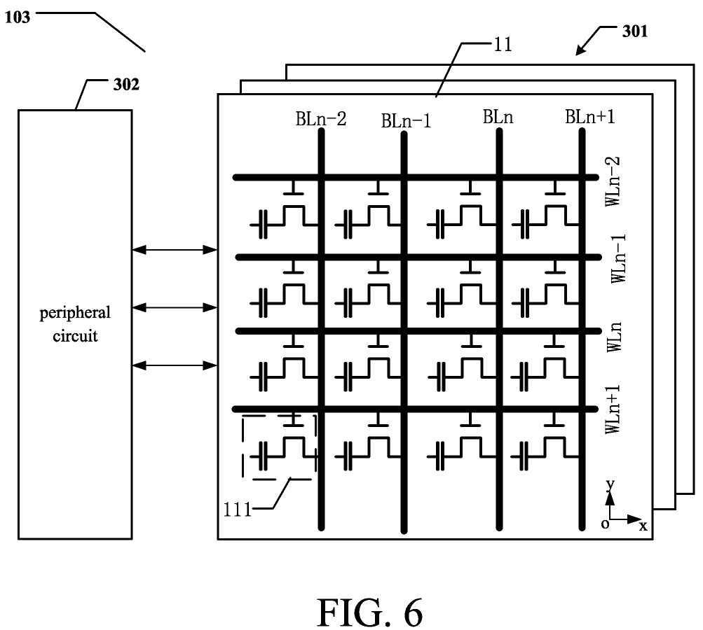

FIG. 6 is a block diagram of a memory according to an example implementation, and the memory 103 shown in FIG. 6 is a dynamic random access memory (DRAM), for example, a double data rate synchronous dynamic random access memory using a DDR4 memory specification and a DDR5 memory specification, or a low-power double data rate synchronous dynamic random access memory using a LPDDR5 memory specification, etc., but is not limited thereto.

As shown in FIG. 6, the memory array 301 in the memory 103 includes a plurality of memory cell arrays 11, each of the memory cell arrays 11 includes a plurality of rows and columns of memory cells 111, and the memory cells 111 may be addressed by specifying the row and the column of the memory cell array 11 in which it is located. The memory cell array 11 includes a plurality of word lines (WL), such as WLn, WLn+1, WLn-1 and WLn-2 as shown in FIG. 6; the memory array 301 further includes a plurality of bit lines (BL), such as BLn, BLn+1, BLn-1 and BLn-2 as shown in FIG. 6, and the WLs intersect with the BLs. The WL is selected and the memory cell 111 at the intersection of the selected WL is selected to perform a read, write or refresh operation. One memory cell 111 shown in FIG. 6 may include a capacitor and a transistor, and one memory cell may include one transistor and one capacitor. The gate of the transistor is coupled to a WL, a controlled terminal (e.g., the source) of the transistor is coupled to one electrode (referred to as a first electrode) of the capacitor, another controlled terminal (e.g., the drain) of the transistor is coupled to the BL, and another electrode (referred to as a second electrode) of the capacitor may be grounded or applied with other voltage (e.g., Vcc/2). As shown in FIG. 6, the memory cells 111 are arranged in an array of x rows and y columns, the rows and columns may be perpendicular or not perpendicular, the extending direction of the WLs may be parallel to the x direction or have an included angle with the x direction, the extending direction of the BLs may be parallel to the y direction or have an included angle with the y direction, and the orthographic projection of the WLs on the xoy plane and the orthographic projection of the BL on the xoy plane are perpendicular, or not perpendicular but with a certain included angle, which is not limited in the implementations of this application. During a read or write operation, a corresponding WL may be selected by using a word line selection signal, a corresponding BL may be selected according to a column selection signal, and simultaneously selecting a WL and a BL may position a selected memory cell so as to perform a read/write operation on it.

In some implementations, a capacitor represents logically 1 and 0 by the amount of charge stored therein, or by the high and low voltage difference across the capacitor. The voltage signal on the WL is applied to the gate to control the transistor to be turned on or turned off, realizing selection and non-selection of the capacitor, thereby reading the data information stored in the capacitor through the BL, or writing data into the capacitor through the BL for storage.

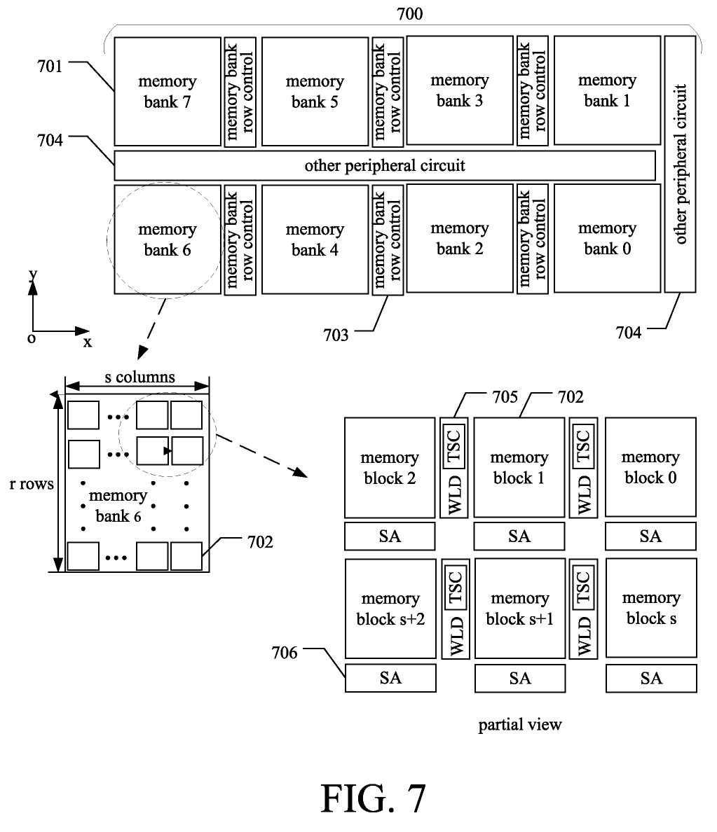

In some implementations, the memory cell array 11 may be divided into memory banks and memory blocks according to the layout design of the memory device. Taking FIG. 7 as an example, FIG. 7 is a schematic diagram of a view of a memory in a direction perpendicular to a stacking direction according to an example implementation, as shown in a view 700 in FIG. 7, the memory array 301 includes a plurality of memory banks 701, for example, 8 memory banks 701. In some implementations, the memory array 301 may further include more than 8 or less than 8 memory banks 701. Here, the number of memory banks 701 in the memory array 301 is not limited in the implementations of this application. The plurality of memory banks 701 are arranged in rows and columns.

Each memory bank 701 includes r×s memory blocks 702 arranged in an array, for example, r rows and s columns of memory blocks 702, and each memory block 702 includes one or more memory arrays 11. Here, values of r and s are not limited in the implementations of this application.

In some implementations, the peripheral circuit 302 includes one or more memory bank row control circuits 703. Each of the memory bank row control circuits 703 includes a memory bank row decoder (XDEC). Through interconnects on the bonding interface 303, the memory bank row decoder is electrically connected to a WL coupled to the bonding interface 303. The memory bank row decoder may be configured to address the row in which the memory bank 701 is located and apply an operating voltage to the WL within the addressed row of memory bank. For ease of description, the area between two adjacent memory banks in the memory array 301 is referred to as a memory bank gap, and the area of the peripheral circuit 302 in which the memory bank row control circuit 703 is disposed is referred to as a row control circuit area, that is, the peripheral circuit 302 includes at least one row control circuit area, and the memory bank row control circuit 703 is disposed in each row control circuit area.

The arrangement of the memory bank row control circuits 703 on the peripheral circuit 302 is related to the arrangement of memory banks in the memory array 301 in the x-direction. For example, in the stacking direction, the memory bank row control circuit 703 is located directly above or directly below a memory bank gap in the x-direction in the memory array 301, which may be expressed as: in the view 700, the row control circuit area overlaps with the memory bank gap between two adjacent memory banks 701 in the x-direction. For example, in the view 700, in the x-direction, there is one memory bank row control circuit 703 between memory bank 0 and memory bank 2, and there is one memory bank row control circuit 703 between memory bank 2 and memory bank 4.

In some implementations, the peripheral circuit 302 further includes a word line driver (WLD) circuit 705 and a sense amplifier (SA) circuit 706. Through interconnects on the bonding interface 303, the WLD circuit 705 is electrically connected to a WL coupled to the bonding interface 303. The WLD circuit 705 is configured to drive the WL using a WL voltage. Through interconnects on the bonding interface 303, the SA circuit 706 is electrically connected to a BL coupled to the bonding interface 303. The SA circuit 706 is configured to sense a low power signal from the BL representing a data bit stored in a memory cell and amplify a small voltage swing to an identifiable logic level in a read operation. The area between two adjacent memory blocks in the same memory bank 701 is referred to as a memory block gap. The area of the peripheral circuit 302 in which the WLD circuit 705 is disposed is referred to as a WLD circuit area, and the area of the peripheral circuit 302 in which the SA circuit 706 is disposed is referred to as an SA circuit area, that is, the peripheral circuit 302 includes a plurality of WLD circuit areas and a plurality of SA circuit areas.

The arrangement of WLD circuits 705 and SA circuits 706 on the peripheral circuit 302 is related to the arrangement of memory blocks in the memory bank 701. For example, in the stacking direction, a WLD circuit 705 is located directly above or directly below a memory block gap in the x direction in the same memory bank, which may be expressed as: in the view 700, the WLD circuit area overlaps with the memory block gap between two adjacent memory blocks 702 in the x direction in the same memory bank. Taking the memory blocks 702 in memory bank 6 shown in FIG. 7 as an example, in the view 700, there is a WLD circuit 705 between memory block 0 and memory block 2 in the x-direction.

In the stacking direction, a SA circuit 706 is located directly above or directly below a memory block gap in the y-direction in the same memory bank, which may be expressed as: in the view 700, the SA circuit area overlaps with the memory block gap between two adjacent memory blocks 702 in the y-direction in the same memory bank. Taking the memory block 702 in the memory bank 6 shown in FIG. 7 as an example, in the view 700, there is a block SA circuit 706 between the memory block 0 and the memory blocks in the y-direction.

In some implementations, the peripheral circuit 302 further includes other peripheral circuits 704 in addition to the memory bank row control circuits 703, the WLD circuits 705, and the SA circuits 706, and the implementations of this application do not limit the other peripheral circuits 704.

In some implementations, the memory array 301 further includes a plurality of target connection lines which may be through silicon contacts (TSC) or other connection lines. Taking target connection lines being TSC as an example, as shown in the cross-sectional view of the memory 103 in (a) of FIG. 5, the memory 103 further includes a bottom metal layer (BTM) which is bonded to the memory array 301 (not shown in FIG. 5) on the first wafer through the bonding interface 304. The BTM is also referred to as the bottom metal layer of the memory array 301. In the first wafer, one end of each TSC in the memory array 301 is electrically connected (e.g., coupled) to the BTM through the bonding interface 304, and the other end of each TSC is electrically connected (e.g., coupled) to the top metal layer (TM) of the peripheral circuit 302 on the second wafer through the connection circuit (Pepper) in the bonding interface 303, so that the TSC can penetrate through each metal layer of the memory array 301 and connect the BTM to the TM. As shown in the top view of the memory 103 in (b) of FIG. 5, the analog module in the peripheral circuit 302 provides an electrical signal to the TM in the vertical direction (that is, the z-direction), the TM transmits the electrical signal to each TSC in the memory array 301 through the bonding interface 303, each TSC transmits the electrical signal provided by the TM to the BTM which spans the entire chip and electrically transmits the electrical signal provided by the TM to each memory bank 701 in the memory array 301. The electrical signal may be a power signal for supplying power to the memory array, and in this case, the analog module is a power supply module for providing the power signal. The BTM may provide a power signal to the memory array 301 to power the memory array 301. For example, the M4 power line in the memory array 301 in the horizontal direction (that is, the x direction) is electrically connected to the memory block 702 in the memory array 301, the BTM is electrically connected to the M4 power line, and the BTM provides a power signal to each memory bank 701 in the memory array 301 through the M4 power line. Each TSC in the memory array 301 is networked into a power network, and the TM transmits a power signal to the BTM through the power network, so that the BTM supplies power to each memory bank 701 in the memory array 301.

In some implementations, a target connection line may be disposed in the memory bank 701, for example, disposed in the area between two adjacent memory blocks 702 of the same memory bank 701. For example, the area of the memory array 301 in which the target connection line (for example, TSC) is disposed is referred to as a target connection line area, and in the view 700, the target connection line area overlaps with a WLD circuit area. For example, in the view 700, the WLD circuit area between memory block 0 and memory block 1 overlaps with the target connection line area.

Target connection lines disposed in a memory bank 701 occupy the space in the memory bank 701, so that more memory blocks 702 cannot be disposed in the memory bank 701, resulting in a low storage capacity of the memory bank 701. Based on this, in this application, the layout of the target connection lines in the memory array 301 shown in FIG. 7 is changed. In an example, the target connection lines are not disposed in the memory bank 701, but disposed between two adjacent memory banks 701, to transfer the target connection lines from the inside of the memory bank 701 to the outside of the memory bank 701, so as to release the space occupied by the target connection lines in the memory bank 701, so that the memory bank 701 can accommodate more or larger memory blocks 702, thereby increasing the storage capacity of a single memory bank without changing the size of the memory bank 701, and further increasing the storage capacity of the memory without changing the size of the memory.

It should be understood that the manner in which the target connection lines connect to the TM and the BTM when the target connection lines are disposed between the memory banks 701 is the same as the manner when the target connection lines are disposed in the memory bank 701. Taking the target connection line being TSCs as an example, as shown in FIG. 5, TSCs are disposed between two adjacent memory banks 701 in the memory array 301 on the first wafer, one end of these TSCs is electrically connected to the TM of the peripheral circuit 302 on the second wafer through the bonding interface 303, and the other end is electrically connected to the BTM through the bonding interface 304, so that the TM provides an electrical signal to the BTM through the TSCs between two adjacent memory banks in the memory array 301, and then the BTM provides the electrical signal to the memory banks of the memory array 301.

Next, the manner in which the target connection lines are disposed between the memory banks 701 is described.

Target connection lines may be disposed between two adjacent memory banks 702 of the memory array 301. For example, in the memory array 301, target connection lines are disposed every two adjacent memory banks 701 in the x direction, and in this case, the target connection lines disposed outside the memory bank 702 include only the first connection lines L1 or only the second connection lines L2, wherein the first connection lines L1 are the target connection lines disposed in a first area between two adjacent memory banks 701, and the second connection lines L2 are the target connection lines disposed in a fifth area between two adjacent memory banks 701. The first area is the area (that is, a memory bank gap) between two adjacent memory banks in the x-direction in the memory array 301, one of the two adjacent memory banks is referred to as a first memory bank, and the other memory bank is referred to as a second memory bank, that is, the two adjacent memory banks include the first memory bank and the second memory bank. If the first memory bank is further adjacent to other memory bank in the memory array 301 in the x direction, the other memory bank is referred to as a third memory bank, that is, in the x direction, the first memory bank is located between the second memory bank and the third memory bank, the first memory bank is adjacent to the second memory bank and the third memory bank, and the second memory bank is not adjacent to the third memory bank. To facilitate distinguishing the areas between the first memory bank and different memory banks in the x-direction, the area between the first memory bank and the second memory bank in the memory array 301 is referred to as the first area, and the area between the first memory bank and the third memory bank in the memory array 301 is referred to as the fifth area. It should be understood that the first area and the fifth area are memory bank gaps between the first memory bank and different memory banks. The sizes of the first area and the fifth area may be the same or different. Taking different sizes as an example, the size of the fifth area is greater than the size of the first area, or the size of the fifth area is less than the size of the first area.

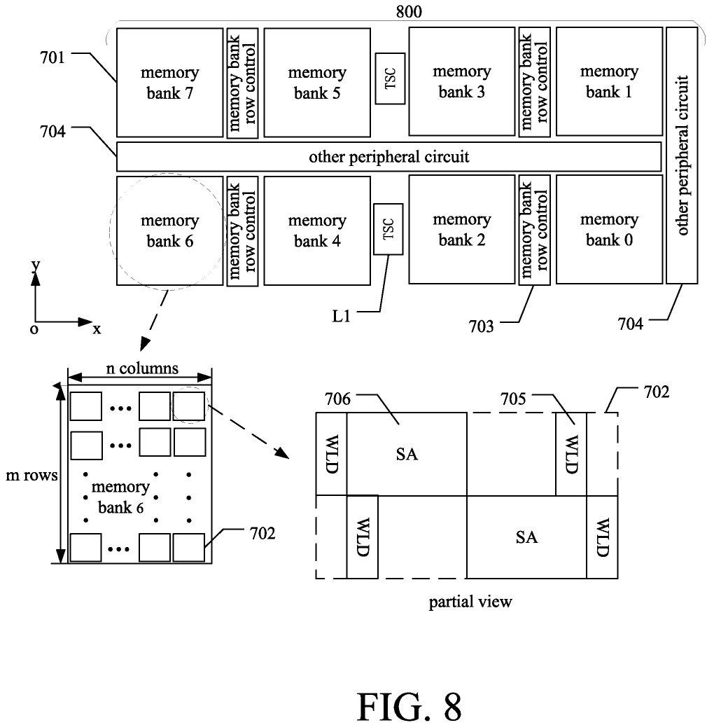

Taking the example that the target connection lines disposed outside the memory bank 702 only includes the first connection lines L1, at least one of the first connection lines L1 is disposed in the first area between two adjacent memory banks 702. The memory array 301 includes a plurality of first areas, and at least one of the first connection lines L1 is disposed in each first area. Taking the first connection line L1 being TSC as an example, as shown in the view 800 of another memory in the direction perpendicular to the stacking direction provided in FIG. 8, it is assumed that the first memory bank is the memory bank 2 in the memory array 301, in the x direction, the TSC (e.g., a first connection line L1) is disposed in the area between the memory bank 2 and the memory bank 4 (e.g., the first area), and no TSC is disposed in the area between the memory bank 2 and the memory bank 0 (e.g., the fifth area).

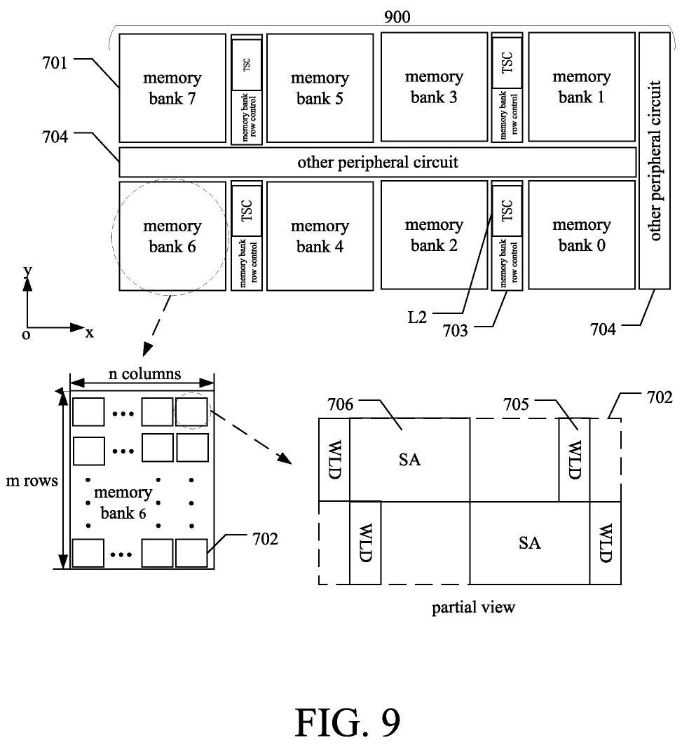

Taking another example that the target connection lines disposed outside the memory bank 702 only includes the second connection lines L2, at least one of the second connection lines L2 is disposed in the fifth area between two adjacent memory banks 702. The memory array 301 includes a plurality of fifth areas, and at least one of the second connection lines L2 is disposed in each fifth area. Taking the second connection line L2 being TSC as an example, as shown in the view 900 of another memory in the direction perpendicular to the stacking direction provided in FIG. 9, it is assumed that the first memory bank is the memory bank 2 in the memory array 301, in the x direction, no TSC is disposed in the area between the memory bank 2 and the memory bank 4 (e.g., the first area), and the TSC (e.g., the second connection line L2) is disposed in the area between the memory bank 2 and the memory bank 0 (e.g., the fifth area).

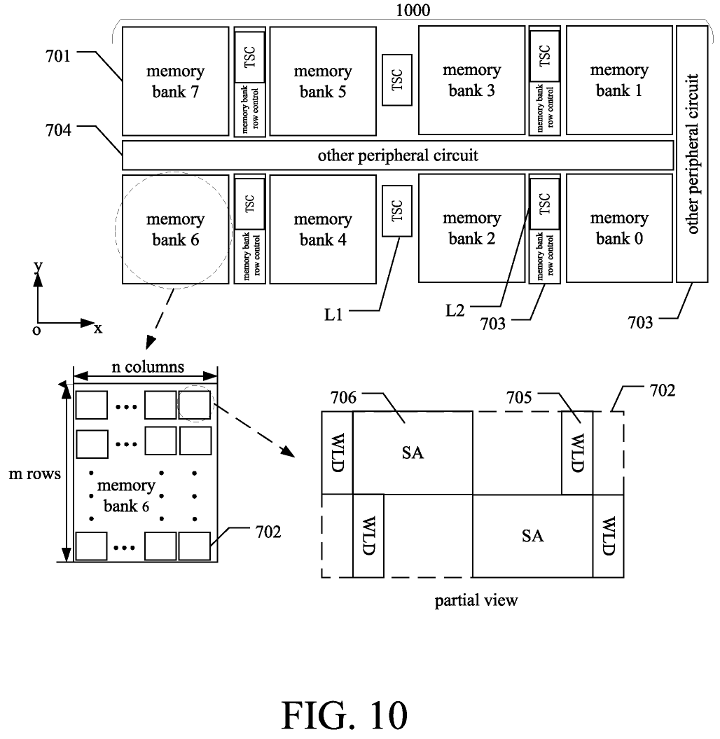

In some other implementations, in the memory array 301, the target connection lines are disposed every memory bank 701 in the x direction, and in this case, the disposed target connection lines include the first connection lines L1 and the second connection lines L2. For example, for a second memory bank, a first memory bank, and a third memory bank that are adjacent in the x direction, at least one of the first connection lines L1 is disposed in the first area between the first memory bank and the second memory bank, and at least one of the second connection lines L2 is disposed in the fifth area between the first memory bank and the third memory bank. Taking the first connection line L1 and the second connection line L2 being TSC as an example, as shown in the view 1000 of another memory in the direction perpendicular to the stacking direction provided in FIG. 10, it is assumed that the first memory bank is the memory bank 2, in the x direction, the TSC (e.g., the first connection line L1) is disposed in the area between the memory bank 2 and the memory bank 4 (e.g., the first area), and the TSC (e.g., the second connection line L2) is disposed in the area between the memory bank 2 and the memory bank 0 (e.g., the fifth area), and in this case, the top view of the memory 103 from BTM to TM may be as shown in (b) of FIG. 5.

Compared with the manner that the target connection lines are disposed every two adjacent memory banks 701, and the manner that the target connection lines are disposed every one memory bank 701, more target connection lines can be disposed in the memory array 301, so that the wiring from the target connection line, the BTM, and the memory bank to the M4 power line is shorter, and a transmission distance of an electrical signal (such as a power signal) from the target connection line to the M4 power line is shorter, thereby reducing a voltage drop (that is, an IR voltage drop) of the electrical signal inside the memory bank.

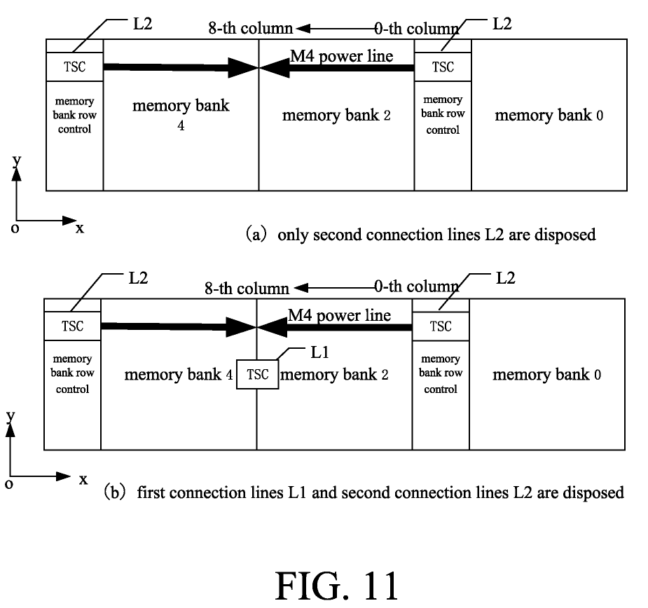

As shown in FIG. 11, assuming that each memory bank includes 9 columns of memory blocks such as the 0-th column to 8-th column, taking the memory bank 2 as an example, if only the second connection lines L2 are disposed, when the electrical signal is transmitted from the power network formed by the second connection lines L2 to the memory blocks in the 5-th column to the 8-th column in the memory bank 2 through BTM, the transmission distance of the electrical signal is relatively long, resulting in a relatively large reduction of the voltage drop of the electrical signal in the memory bank 2. If the first connection lines L1 and the second connection lines L2 are disposed, when an electrical signal is transmitted from the power network formed by the first connection lines L1 and the second connection lines L2 to the memory blocks in the 5-th column to the 8-th column in the memory bank 2 through the BTM, the transmission distance of the electrical signal is relatively short, and the voltage loss in the transmission process is small, so that the voltage drop of the electrical signal in the memory bank 2 can be reduced.

After testing, when only the second connection lines L2 are disposed, the decreasing amplitude of the voltage drop of the memory bank may be up to 0.21V, and when the first connection lines L1 and the second connection lines L2 are disposed, the decreasing amplitude of the voltage drop of the memory bank can be reduced to 0.14V, and the overall benefit of one memory bank is approximately 60%.

The area of the peripheral circuit 302 in which the memory bank row control circuit is disposed may also be referred to as a second area (that is, a memory bank row circuit area), and in the stacking direction, the second area is located directly below or directly above a fifth area, and is not located directly below or directly above a first area, which can be expressed as: in the view of the memory perpendicular to the stacking direction, the second area overlaps with the first area, and does not overlap with the fifth area. Taking the view 800, the view 900, and the view 1000 as an example, assuming that the memory bank 2 in the memory array 301 is the first memory bank and the memory bank 0 is the third memory bank, in the view 800, the view 900, and the view 1000, the area of the peripheral circuit 302 in which the memory bank row control circuit 703 is located (e.g., a second area) overlaps with the area between the memory bank 2 and the memory bank 0 in the memory array 301 (e.g., a fifth area), and the area of the peripheral circuit 302 in which the memory bank row control circuit 703 is located (e.g., the second area) does not overlap with the area between the memory bank 2 and the memory bank 4 (e.g., a first area).

In the case that the target connection lines are disposed between the memory banks, no target connection line is disposed in each memory bank 701 of the memory array 301, so that more memory blocks or memory blocks with larger size can be placed in a single memory bank.

As shown in the view 800, the view 900, and the view 1000, the memory array 301 includes a plurality of memory banks 701, taking target connection lines being TSC as an example, no TSC is disposed in each memory bank 701. Each memory bank 701 includes m×n memory blocks 702 which are arranged in an array, for example, m rows and n columns of memory blocks 702, wherein both m and n are integers greater than 1, n may be greater than or equal to r, and m may be greater than or equal to s. Here, n and m are not limited in the implementations of this application.

The distribution of the target connection lines in the memory array 301 outside the memory bank is described above, and the arrangement of the target connection lines in the memory bank gap is related to the arrangement of the memory blocks within the memory banks. Next, taking each memory bank 701 including m rows of memory blocks 702 as an example, the arrangement of target connection lines in the memory bank gaps will be introduced. Taking the first area between two adjacent memory banks as an example, the arrangement of target connection lines in the first area will be introduced.

In some implements, in the first area, one or two first connection lines L1 are disposed between a same row of memory blocks of two adjacent memory banks.

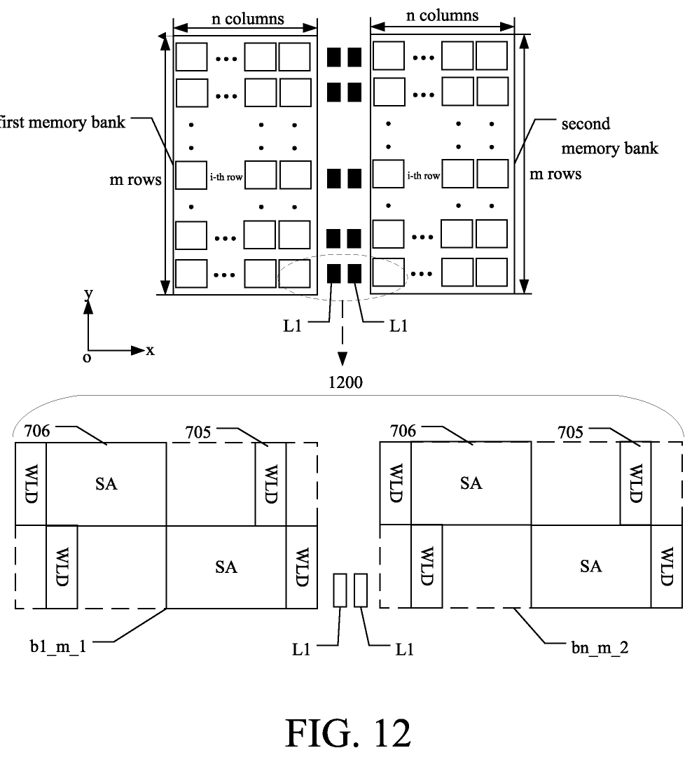

Taking two first connection lines L1 being disposed between a same row of memory blocks of two adjacent memory banks as an example, as shown in FIG. 12, the two adjacent memory banks include a first memory bank and a second memory bank, in the first area between the first memory bank and the second memory bank, two first connection lines L1 are disposed between an i-th row of memory blocks of the first memory bank and an i-th row of memory blocks of the second memory bank, in the x direction, one of the two first connection lines L1 is adjacent to the i-th row of memory blocks of the first memory bank, and the other of the two first connection lines L1 is adjacent to the i-th row of memory blocks of the second memory bank, wherein i is greater than or equal to 1 and less than or equal to m, and i is an integer.

Taking the memory block b1_m_1 of the m-th row and the first column in the first memory bank and the memory block bn_m_2 of the m-th row and the n-th column in the second memory bank as an example, as shown in the partial view 1200 in FIG. 12, the partial view 1200 may be a partial area of the memory in a view (such as the view 800, the view 900, or the view 1000) perpendicular to the stacking direction. In the partial view 1200, two first connection lines L1 are disposed in an area between the memory block b1_m_1 and the memory block bn_m_2 (e.g., a partial area in the first area), and in the x direction, the two first connection lines L1 are located in the same row, and the two first connection lines L1 are adjacent to the memory block b1_m_1 and the memory block bn_m_2 respectively. Of course, the two first connection lines L1 may also be located at any position in the area between the memory blockb1_m_1 and the memory block bn_m_2. As long as the two first connection lines L1 are disposed in the area between the memory block bn_m_1 and the memory block bn_m_2 in the first area, that is enough. Here, the positions of the two first connection lines L1 are not limited in the implementations of this application.

In the first area between the first memory bank and the second memory bank, two first connection lines L1 are disposed between the i-th row of memory blocks of the first memory bank and the i-th row of memory blocks of the second memory bank. As such, in the first area between the first memory bank and the second memory bank, in the y-direction, there are m first connection lines L1 adjacent to the first memory bank and m first connection lines L1 adjacent to the second memory bank, and in the y-direction, the m first connection lines L1 adjacent to the first memory bank may form one column of first connection lines L1, and the m first connection lines L1 adjacent to the second memory bank may form another column of first connection lines L1, where i is greater than or equal to 1 and less than or equal to n, and i is an integer.

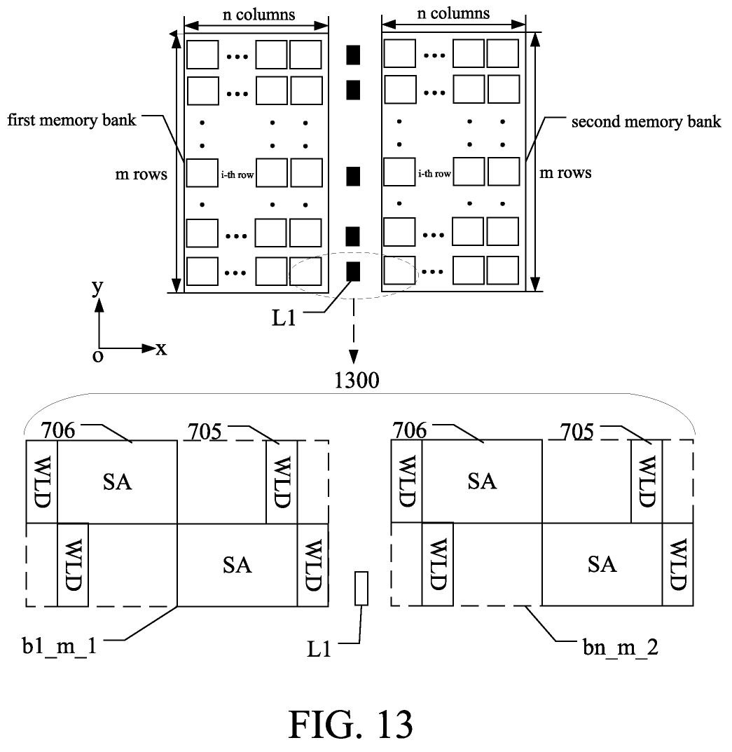

Taking one first connection line L1 being disposed between a same row of memory blocks of two adjacent memory banks, as shown in FIG. 13, the two adjacent memory banks include a first memory bank and a second memory bank, and in the first area between the first memory bank and the second memory bank, one first connection line L1 is disposed between an i-th row of memory blocks of the first memory bank and an i-th row of memory blocks of the second memory bank, and the first connection line is located at a middle position between the i-th row of memory blocks of the first memory bank and the i-th row of memory blocks of the second memory bank.

Taking the memory block b1_m_1 in the m-th row and the first column of the first memory bank and the memory block bn_m_2 in the m-th row and the n-th column of the second memory bank as an example, as shown in the partial view 1300 in FIG. 13, the partial view 1300 may be a partial area of the memory in a view perpendicular to the stacking direction (for example, the view 800, the view 900, or the view 1000). In the partial view 1300, one first connection line L1 is disposed in an area between the memory block b1_m_1 and the memory block bn_m_2 (e.g., a partial area in the first area), and the first connection line L1 is located at a middle position between the memory block b1_m_1 and the memory block bn_m_2. In some implementations, this first connection line L1 may not be located at the middle position between the memory block b1_m_1 and the memory block bn_m_2, for example, the first connection line L1 is close to the memory block b1_m_1 and away from the memory block bn_m_2, or the first connection line L1 is away from the memory block b1_m_1 and close to the memory block bn_m_2. It should be understood that this first connection line L1 may be located anywhere in the area between the memory block b1_m_1 and the memory block bn_m_2. As long as one first connection line L1 is disposed in the area between the memory block bn_m_1 and the memory block bn_m_2 in the first area, that is enough. Here, the position of the first connection line L1 is not limited in the implementations of this application.

When one first connection line L1 is disposed between a same row of memory blocks of two adjacent memory banks, in the first area between the first memory bank and the second memory bank, there are m first connection lines L1 in the y-direction, and the m first connection lines L1 may form a column of first connection lines L1.

In some implementations, taking two adjacent rows of memory blocks of a same memory bank as a scope, one or two first connection lines L1 are disposed in the area adjacent to the two adjacent rows of memory blocks in the first area.

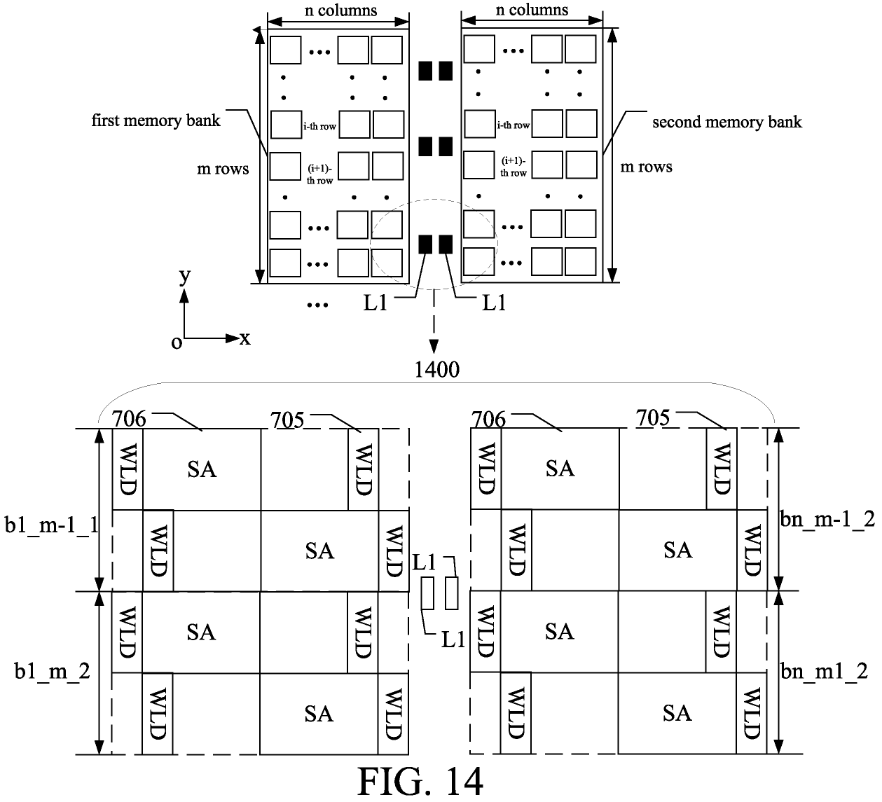

Taking two first connection lines L1 being disposed in the area adjacent to the two adjacent rows of memory blocks in the first area as an example, as shown in FIG. 14, two adjacent memory banks include a first memory bank and a second memory bank, and in the first area between the first memory bank and the second memory bank, two first connection lines L1 are disposed between the i-th row of memory blocks and the (i+1)-th row of memory blocks of the first memory bank and the i-th row of memory blocks and the (i+1)-th row of memory blocks of the second memory bank, wherein, in the x direction, one of the two first connection lines L1 is adjacent to the i-th row of memory blocks and the (i+1)-th row of memory blocks of the first memory bank.

Taking the memory block b1_m-1_1 in the (m-1)-th row and the first column in the first memory bank, the memory block b1_m_1 in the mth row and the first column in the first memory bank, the memory block bn_m-1_2 in the (m-1)-th row and the n-th column in the second memory bank, and the memory block bn_m_2 in the m-th row and the n-th column in the second memory bank as an example, as shown in the partial view 1400 in FIG. 14, the partial view 1400 may be a partial area of the memory in a view (such as the view 800, the view 900 or the view 1000) perpendicular to the stacking direction, in the partial view 1400, two first connection lines L1 are disposed in an area between the memory block b1_m-1_1, the memory block b1_m_1, the memory block bn_m-1_2 and the memory block bn_m_2 (that is, a partial area in the first area), the two first connection lines L1 may be located in a middle area in the area. In the x direction, the two first connection lines L1 are located in the same row, the first connection line L1 located on the left side is adjacent to the memory block bn_m-1_1 and the memory block b1_m_1 respectively, and the first connection line L1 located on the right side is adjacent to the memory block bn_m-1_2 and the memory block b1_m_2 respectively. In another implementation, the two first connection lines L1 may not be located in the middle area of the area, for example, the two first connection lines L1 may be located anywhere in the area between the memory block b1_m-1_1, the memory block bn_m_1, the memory block bn_m-1_2 and the memory block bn_m_2. As long as two first connection lines are disposed in the area between the memory block b1_m-1_1, the memory block bn_m_1, the memory block bn_m-1_2 and the memory block bn_m_2 in the first area, that is enough. Here, the positions of the two first connection lines are not limited in the implementations of this application.

Two first connection lines L1 are disposed in the area adjacent to the two adjacent rows of memory blocks in the first area. As such, in the first area between the first memory bank and the second memory bank, there are m-1 first connection lines L1 adjacent to the first memory bank and m-1 first connection lines L1 adjacent to the second memory bank in the y-direction, and in the y-direction, the m-1 first connection lines L1 adjacent to the first memory bank may form one column of first connection lines L1, and the m-1 first connection lines L1 adjacent to the second memory bank may form another column of first connection lines L1.

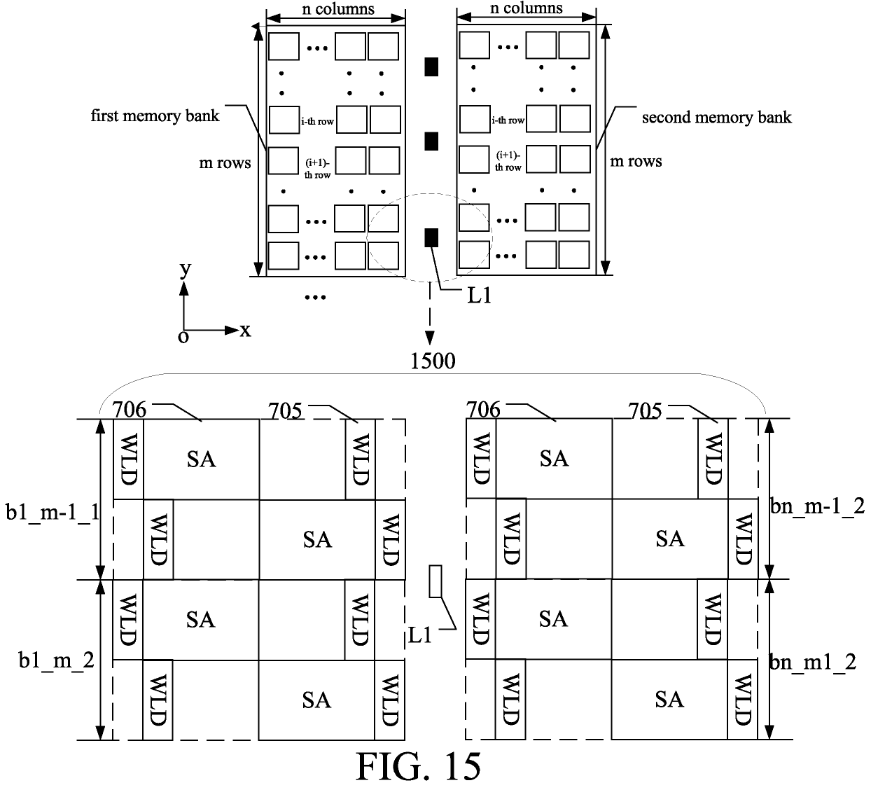

Taking the example that one first connection line is disposed in the area adjacent to the two adjacent rows of memory blocks in the first area, as shown in FIG. 15, two adjacent memory banks include a first memory bank and a second memory bank, and in the first area between the first memory bank and the second memory bank, one first connection line L1 is disposed between the i-th row of memory blocks and the (i+1)-th row of memory blocks of the first memory bank and the i-th row of memory blocks and the (i+1)-th row of memory blocks of the second memory bank, wherein the first connection line L1 is located at a middle position between the i-th row of memory blocks and the (i+1)-th row of memory blocks of the first memory bank and the i-th row of memory blocks and the (i+1)-th row of memory blocks of the second memory bank. In the first area between the first memory bank and the second memory bank, there are m-1 first connection lines L1 in the y-direction, and the m-1 first connection lines L1 form a column of first connection lines L1.

Taking the memory block b1_m-1_1 in the (m-1)-th row and the first column in the first memory bank, the memory block b1_m_1 in the m-th row and the first column in the first memory bank, the memory block bn_m-1_2 in the (m-1)-th row and the n-th column in the second memory bank, and the memory block bn_m_2 in the m-th row and the n-th column in the second memory bank as an example, as shown in a partial view 1500 in FIG. 15, the partial view 1500 may be a partial area of the memory in a view perpendicular to the stacking direction (such as the view 800, the view 900, or the view 1000). In the partial view 1500, one first connection line L1 is disposed at a middle position in the area between the memory block b1_m-1_1, the memory block bn_m_1, the memory block bn_m-1_2 and the memory block bn_m_2 (e.g., a partial area in the first area). In some implementations, this first connection line L1 may not be located in the middle position between the memory block b1_m-1_1, the memory block bn_m_1, the memory block bn_m-1_2 and the memory block bn_m_2, for example, the first connection line L1 is close to one of the memory block b1_m-1_1, the memory block bn_m_1, the memory block bn_m-1_2 and the memory block bn_m_2, but away from other memory blocks. As long as one first connection line L1 is disposed in the area between the memory block b1_m-1_1, the memory block bn_m_1, the memory block bn_m-1_2 and the memory block bn_m_2 in the first area, that is enough. Here, the position of this first connection line L1 is not limited in the implementations of this application.

When one first connection line L1 is disposed in the area adjacent to the two adjacent rows of memory blocks in the first area, in the first area between the first memory bank and the second memory bank, there are m-1 first connection lines L1 in the y-direction, and the m-1 first connection lines L1 may form a column of first connection lines L1.

FIG. 12 to FIG. 15 illustrate that 2m, m, 2*(m-1) or (m-1) first connection lines L1 are disposed in the first area between adjacent memory banks. In some other implementations, fewer first connection lines L1 may be disposed, and taking FIG. 12 and FIG. 13 as an example, no the first connection line L1 may be disposed between the first row of memory blocks of the first memory bank and the first row of memory blocks of the second memory bank, and/or, no the first connection line L1 may be disposed between the m-th row of memory blocks of the first memory bank and the m-th row of memory blocks of the second memory bank. Of course, if the first area is large enough, more first connection lines L1 may also be disposed in the first area. Here, the number of the first connection lines L1 in the first area and the position of each first connection line L1 are not limited in the implementations of this application.

In the case where the second connection lines L2 are disposed in the fifth area, the manner is the same as the manner in which the first connection lines L1 are disposed in the first area, and details are not described herein again. It should be understood that, in the case that the size of the fifth area is greater than the size of the first area, more second connection lines L2 may be disposed in the fifth area relative to the first area. Here, the number of the second connection lines L2 in the fifth area and the position of each second connection line L2 are not limited in the implementations of this application.

In the case that the target connection lines are disposed in the area between the memory banks 701 in the memory array 301, the target connection line is not disposed within each memory bank 701, that is, no target connection line is disposed in each memory bank 701, so that the memory banks 701 can accommodate more memory blocks or memory blocks with larger size without reducing the size of the memory banks 701, thereby improving the storage capacity of a single memory bank, and further improving the storage capacity of the memory. In addition, when the memory is reduced or the size of the memory bank is reduced, no target connection line is disposed in the memory bank, so that the memory bank can have a sufficient quantity or a sufficient capacity of memory blocks to ensure the storage capacity of a single memory bank, thereby ensuring the storage capacity of the memory.

In a case where no target connection line is disposed in the memory bank 701, no connection line (such as a target connection line) for connecting the peripheral circuit is disposed in an area between adjacent memory blocks of the same memory bank 701. In this case, in some implementations, the arrangement of the WLD circuit 705 and the SA circuit 706 in the peripheral circuit 302 may also be adjusted. In the stacking direction, the WLD circuit 705 and the SA circuit 706 are located directly below or directly above the memory block 702. An area of the memory bank 701 in which the memory block 702 is disposed is referred to as a third area (that is, a memory block area), that is, the memory bank 701 includes a plurality of third areas, and one memory block 702 is disposed in each third area. An area of the peripheral circuit 302 in which the WLD circuit 705 and the SA circuit 706 are disposed is referred to as a fourth area, that is, the peripheral circuit 302 includes a plurality of fourth areas, and at least one WLD circuit 705 and at least one SA circuit 706 are disposed in each fourth area.

In the stacking direction, the WLD circuits 705 and the SA circuits 706 are located directly below or directly above the memory block 702, which may be expressed as: in a view of the memory 103 perpendicular to the stacking direction, a third area in the memory bank 701 overlaps with a fourth area in the peripheral circuit 302. Taking partial views in the view 800, the view 900 and the view 1000, and partial views 1200,1300, 1400 and 1500 as an example, in these partial views, a dashed box is used for representing an area in the memory bank in which one memory block is located (that is, a third area), and in these partial views, an area in which one memory block is located (that is, a third area) overlaps with an area in which the WLD circuit 705 and the SA circuit 706 are located (that is, a fourth area).

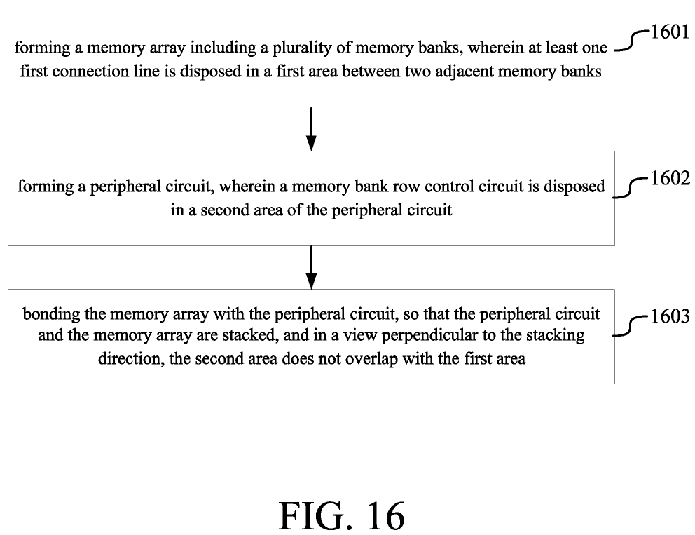

Based on the foregoing memory 103, this application further provides a method for forming a memory, and as shown in FIG. 16, a flowchart of a method for forming the memory is provided by an implementation of this application, the method is used for forming the memory 103 described above and includes the following operations.

1601 : forming a memory array including a plurality of memory banks, wherein at least one first connection line is disposed in a first area between two adjacent memory banks.

The first connection line is the first connection line L1 described above. The memory array may be any memory array 301 described above in which a first connection line is disposed in the first area. A memory array may be formed on the first wafer, and in the process of forming the memory array, the first connection line may also be formed in each first area of the memory array. In some other implementations, the second connection line may also be formed in each third area of the memory array. The distribution of the first connection line and the second connection line in the memory array is as described above and will not be described in detail here.

1602 : forming a peripheral circuit, wherein a memory bank row control circuit is disposed in a second area of the peripheral circuit.

The peripheral circuit may be the peripheral circuit 302 described in FIG. 8 to FIG. 10. The peripheral circuits may be formed on the second wafer. During the formation of the peripheral circuit, a memory bank row control circuit is formed on the second area of the peripheral circuit, and at least one WLD circuit and at least one SA circuit are formed on the fourth area of the peripheral circuit.

1603 : bonding the memory array with the peripheral circuit, so that the peripheral circuit and the memory array are stacked, and in a view perpendicular to the stacking direction, the second area does not overlap with the first area.

For example, the memory array and the peripheral circuit are bonded through a bonding interface (for example, the bonding interface 303), so that the memory array and the peripheral circuit are bonded into a whole, and in a view perpendicular to the stacking direction, the second area in the peripheral circuit does not overlap with the first area, and the second area in the peripheral circuit overlaps with the third area in the memory array.

According to the method provided by the implementation of this application, by disposing the first connection line between the memory banks of a memory array and not disposing the first connection line within the memory bank, the memory banks are enabled to accommodate more memory blocks or memory blocks with larger size, thereby increasing the storage capacity of a single memory bank without changing the size of the memory bank, and thus increasing the storage capacity of the memory without changing the size of the memory.

Implementations of this application provide a memory, a memory system, and a method for forming the memory, to improve storage capacity of the memory. The stated solutions are as follows.

In a first aspect, a memory is provided, the memory including: a memory array including a plurality of memory banks, wherein at least one first connection line is disposed in a first area between two adjacent memory banks; and a peripheral circuit stacked with the memory array and electrically connected with the first connection line, wherein a memory bank row control circuit is disposed in a second area of the peripheral circuit, and in a view of the memory perpendicular to a stacking direction, the second area does not overlap with the first area.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks of the first memory bank and an i-th row of memory blocks of the second memory bank, and wherein i is greater than or equal to 1 and less than or equal to m.

In an example, when one first connection line is disposed between the i-th row of memory blocks of the first memory bank and the i-th row of memory blocks of the second memory bank, the one first connection line is located at a middle position between the i-th row of memory blocks of the first memory bank and the i-th row of memory blocks of the second memory bank; and when two first connection lines are disposed between the i-th row of memory blocks of the first memory bank and the i-th row of memory blocks of the second memory bank, one of the two first connection lines is adjacent to the i-th row of memory blocks of the first memory bank, and the other connection line is adjacent to the i-th row of memory blocks of the second memory bank.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks and an (i+1)-th row of memory blocks of the first memory bank and an i-th row of memory blocks and an (i+1)-th row of memory blocks of the second memory bank, and wherein i is greater than or equal to 1 and less than m.

In an example, when one first connection line is disposed between the i-th row of memory blocks and the (i+1)-th row of memory blocks of the first memory bank and the i-th row of memory blocks and the (i+1)-th row of memory blocks of the second memory bank, the one first connection line is located at a middle position between the i-th row of memory blocks and the (i+1)-th row of memory blocks of the first memory bank and the i-th row of memory blocks and the (i+1)-th row of memory blocks of the second memory bank; and when two first connection lines are disposed between the i-th row of memory blocks and the (i+1)-th row of memory blocks of the first memory bank and the i-th row of memory blocks and the (i+1)-th row of memory blocks of the second memory bank, one of the two first connection lines is adjacent to the i-th row of memory blocks and the (i+1)-th row of memory blocks of the first memory bank, and the other connection line is adjacent to the i-th row of memory blocks and the (i+1)-th row of memory blocks of the second memory bank.

In an example, each of the memory banks includes a plurality of memory blocks, and no connection line for connecting the peripheral circuit is disposed in an area between adjacent memory blocks of a same memory bank.

In an example, a memory block is disposed in a third area of each of the memory banks; and a word line driver circuit and a sense amplifier circuit are disposed in a fourth area of the peripheral circuit, wherein the fourth area overlaps with the third area in the view.

In an example, the two adjacent memory banks include a first memory bank and a second memory bank, the first memory bank is further adjacent to a third memory bank, and in the view, a fifth area between the first memory bank and the third memory bank overlaps with the second area.

In an example, a second connection line is disposed in the fifth area, and the second connection line is different from the first connection line.

In an example, the first connection line is coupled with a top metal layer of the peripheral circuit and a bottom metal layer of the memory array; and the second connection line is coupled with the top metal layer of the peripheral circuit and the bottom metal layer of the memory array.

In an example, the memory array is bonded with the peripheral circuit.

In a second aspect, a memory system is provided, the memory system including a memory and a memory controller coupled to the memory; the memory includes a memory array and a peripheral circuit stacked with the memory array, wherein the memory array includes a plurality of memory banks, at least one first connection line is disposed in a first area between two adjacent memory banks, and the peripheral circuit is electrically connected to the first connection line, a memory bank row control circuit is disposed in a second area of the peripheral circuit, and in a view of the memory perpendicular to a stacking direction, the second area does not overlap with the first area; and the memory controller is configured to control operation of the memory array via the peripheral circuit.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks of the first memory bank and an i-th row of memory blocks of the second memory bank, and wherein i is greater than or equal to 1 and less than or equal to m.

In an example, when one first connection line is disposed between the i-th row of memory blocks of the first memory bank and the i-th row of memory blocks of the second memory bank, the one first connection line is located at a middle position between the i-th row of memory blocks of the first memory bank and the i-th row of memory blocks of the second memory bank; and when two first connection lines are disposed between the i-th row of memory blocks of the first memory bank and the i-th row of memory blocks of the second memory bank, one of the two first connection lines is adjacent to the i-th row of memory blocks of the first memory bank, and the other connection line is adjacent to the i-th row of memory blocks of the second memory bank.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks and an (i+1)-th row of memory blocks of the first memory bank and an i-th row of memory blocks and an (i+1)-th row of memory blocks of the second memory bank, and wherein i is greater than or equal to 1 and less than m.

In an example, when one first connection line is disposed between the i-th row of memory blocks and the (i+1)-th row of memory blocks of the first memory bank and the i-th row of memory blocks and the (i+1)-th row of memory blocks of the second memory bank, the one first connection line is located at a middle position between the i-th row of memory blocks and the (i+1)-th row of memory blocks of the first memory bank and the i-th row of memory blocks and the (i+1)-th row of memory blocks of the second memory bank; and when two first connection lines are disposed between the i-th row of memory blocks and the (i+1)-th row of memory blocks of the first memory bank and the i-th row of memory blocks and the (i+1)-th row of memory blocks of the second memory bank, one of the two first connection lines is adjacent to the i-th row of memory blocks and the (i+1)-th row of memory blocks of the first memory bank, and the other connection line is adjacent to the i-th row of memory blocks and the (i+1)-th row of memory blocks of the second memory bank.

In an example, each of the memory banks includes a plurality of memory blocks, and no connection line for connecting the peripheral circuit is disposed in an area between adjacent memory blocks of a same memory bank.

In an example, a memory block is disposed in a third area of each of the memory banks; and a word line driver circuit and a sense amplifier circuit are disposed in a fourth area of the peripheral circuit, wherein the fourth area overlaps with the third area in the view.

In an example, the two adjacent memory banks include a first memory bank and a second memory bank, the first memory bank is further adjacent to a third memory bank, and in the view, a fifth area between the first memory bank and the third memory bank overlaps with the second area.

In an example, a second connection line is disposed in the fifth area, and the second connection line is different from the first connection line.

In an example, the first connection line is coupled with a top metal layer of the peripheral circuit and a bottom metal layer of the memory array; and the second connection line is coupled with the top metal layer of the peripheral circuit and the bottom metal layer of the memory array.

In an example, the memory array is bonded with the peripheral circuit.

In a third aspect, a method for forming a memory is provided, the method including: forming a memory array including a plurality of memory banks, wherein at least one first connection line is disposed in a first area between two adjacent memory banks; forming a peripheral circuit, wherein a memory bank row control circuit is disposed in a second area of the peripheral circuit; and bonding the memory array with the peripheral circuit, so that the peripheral circuit and the memory array are stacked, and in a view perpendicular to a stacking direction, the second area does not overlap with the first area.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks of the first memory bank and an i-th row of memory blocks of the second memory bank, and wherein i is greater than or equal to 1 and less than or equal to m.

In an example, when one first connection line is disposed between the i-th row of memory blocks of the first memory bank and the i-th row of memory blocks of the second memory bank, the one first connection line is located at a middle position between the i-th row of memory blocks of the first memory bank and the i-th row of memory blocks of the second memory bank; and when two first connection lines are disposed between the i-th row of memory blocks of the first memory bank and the i-th row of memory blocks of the second memory bank, one of the two first connection lines is adjacent to the i-th row of memory blocks of the first memory bank, and the other connection line is adjacent to the i-th row of memory blocks of the second memory bank.

In an example, each of the memory banks includes m rows of memory blocks, wherein m is greater than or equal to 1; and the two adjacent memory banks include a first memory bank and a second memory bank, wherein one or two first connection lines are disposed between an i-th row of memory blocks and an (i+1)-th row of memory blocks of the first memory bank and an i-th row of memory blocks and an (i+1)-th row of memory blocks of the second memory bank, and wherein i is greater than or equal to 1 and less than m.

In an example, when one first connection line is disposed between the i-th row of memory blocks and the (i+1)-th row of memory blocks of the first memory bank and the i-th row of memory blocks and the (i+1)-th row of memory blocks of the second memory bank, the one first connection line is located at a middle position between the i-th row of memory blocks and the (i+1)-th row of memory blocks of the first memory bank and the i-th row of memory blocks and the (i+1)-th row of memory blocks of the second memory bank; and when two first connection lines are disposed between the i-th row of memory blocks and the (i+1)-th row of memory blocks of the first memory bank and the i-th row of memory blocks and the (i+1)-th row of memory blocks of the second memory bank, one of the two first connection lines is adjacent to the i-th row of memory blocks and the (i+1)-th row of memory blocks of the first memory bank, and the other connection line is adjacent to the i-th row of memory blocks and the (i+1)-th row of memory blocks of the second memory bank.

In an example, each of the memory banks includes a plurality of memory blocks, and no connection line for connecting the peripheral circuit is disposed in an area between adjacent memory blocks of a same memory bank.

In an example, a memory block is disposed in a third area of each of the memory banks; and a word line driver circuit and a sense amplifier circuit are disposed in a fourth area of the peripheral circuit, wherein the fourth area overlaps with the third area in the view.

In an example, the two adjacent memory banks include a first memory bank and a second memory bank, the first memory bank is further adjacent to a third memory bank, and in the view, a fifth area between the first memory bank and the third memory bank overlaps with the second area.

In an example, a second connection line is disposed in the fifth area, and the second connection line is different from the first connection line.

In an example, the first connection line is coupled with a top metal layer of the peripheral circuit and a bottom metal layer of the memory array; and the second connection line is coupled with the top metal layer of the peripheral circuit and the bottom metal layer of the memory array.

In the above-described memory, by disposing the first connection line between the memory banks of the memory array and not disposing the first connection line within the memory bank, the memory banks are enabled to accommodate more memory blocks or memory blocks with larger size, thereby increasing the storage capacity of a single memory bank without changing the size of the memory bank, and thus increasing the storage capacity of the memory without changing the size of the memory.

The foregoing descriptions are merely implementations of this application, and are not intended to limit this application, and any modification, equivalent replacement, improvement, and the like made within the spirit and principle of this application shall be included in the protection scope of this application.

What is claimed is:

1. A memory, comprising:
a memory array including a plurality of memory banks, wherein at least one first connection line is disposed in a first area between two adjacent memory banks; and
a peripheral circuit stacked with the memory array in a stacking direction and connected with the first connection line, wherein a memory bank row control circuit is disposed in a second area of the peripheral circuit, and wherein the second area does not overlap with the first area in a plan view perpendicular to the stacking direction.

2. The memory of claim 1, wherein:
each of the memory banks includes m rows of memory blocks, wherein m is greater than or equal to 1; and
the two adjacent memory banks include a first memory bank and a second memory bank, wherein one or two first connection lines are disposed between an i-th row of memory blocks of the first memory bank and an i-th row of memory blocks of the second memory bank, and wherein i is greater than or equal to 1 and less than or equal to m.

3. The memory of claim 2, wherein:
when the one first connection line is disposed between the i-th row of memory blocks of the first memory bank and the i-th row of memory blocks of the second memory bank, the one first connection line is located at a middle position between the i-th row of memory blocks of the first memory bank and the i-th row of memory blocks of the second memory bank; and
when the two first connection lines are disposed between the i-th row of memory blocks of the first memory bank and the i-th row of memory blocks of the second memory bank, one of the two first connection lines is adjacent to the i-th row of memory blocks of the first memory bank, and the other connection line is adjacent to the i-th row of memory blocks of the second memory bank.

4. The memory of claim 1, wherein:
each of the memory banks includes m rows of memory blocks, wherein m is greater than or equal to 1; and
the two adjacent memory banks include a first memory bank and a second memory bank, wherein one or two first connection lines are disposed between an i-th row of memory blocks and an (i+1)-th row of memory blocks of the first memory bank and an i-th row of memory blocks and an (i+1)-th row of memory blocks of the second memory bank, and wherein i is greater than or equal to 1 and less than m.

5. The memory of claim 4, wherein:
when the one first connection line is disposed between the i-th row of memory blocks and the (i+1)-th row of memory blocks of the first memory bank and the i-th row of memory blocks and the (i+1)-th row of memory blocks of the second memory bank, the one first connection line is located at a middle position between the i-th row of memory blocks and the (i+1)-th row of memory blocks of the first memory bank and the i-th row of memory blocks and the (i+1)-th row of memory blocks of the second memory bank; and
when the two first connection lines are disposed between the i-th row of memory blocks and the (i+1)-th row of memory blocks of the first memory bank and the i-th row of memory blocks and the (i+1)-th row of memory blocks of the second memory bank, one of the two first connection lines is adjacent to the i-th row of memory blocks and the (i+1)-th row of memory blocks of the first memory bank, and the other connection line is adjacent to the i-th row of memory blocks and the (i+1)-th row of memory blocks of the second memory bank.

6. The memory of claim 1, wherein each of the memory banks includes a plurality of memory blocks, and no connection line for connecting the peripheral circuit is disposed in an area between adjacent memory blocks of a same memory bank.

7. The memory of claim 1, wherein:
a memory block is disposed in a third area of each of the memory banks; and
a word line driver circuit and a sense amplifier circuit are disposed in a fourth area of the peripheral circuit, wherein the fourth area overlaps with the third area in the view.

8. The memory of claim 1, wherein the two adjacent memory banks include a first memory bank and a second memory bank, the first memory bank is further adjacent to a third memory bank, and in the view, a fifth area between the first memory bank and the third memory bank overlaps with the second area.

9. The memory of claim 8, wherein a second connection line is disposed in the fifth area, and the second connection line is different from the first connection line.

10. The memory of claim 9, wherein the first connection line is coupled with a top metal layer of the peripheral circuit and a bottom metal layer of the memory array; and the second connection line is coupled with the top metal layer of the peripheral circuit and the bottom metal layer of the memory array.

11. The memory of claim 1, wherein the memory array is bonded with the peripheral circuit.

12. A memory system, comprising:
a memory including:
a memory array including a plurality of memory banks, wherein at least one first connection line is disposed in a first area between two adjacent memory banks, and
a peripheral circuit stacked with the memory array and electrically connected with the first connection line, wherein a memory bank row control circuit is disposed in a second area of the peripheral circuit, and in a view of the memory perpendicular to a stacking direction, the second area does not overlap with the first area; and
a memory controller coupled to the memory and configured to control operations of the memory array via the peripheral circuit.

13. The memory system of claim 12, wherein:
each of the memory banks includes m rows of memory blocks, wherein m is greater than or equal to 1; and
the two adjacent memory banks include a first memory bank and a second memory bank, wherein one or two first connection lines are disposed between an i-th row of memory blocks of the first memory bank and an i-th row of memory blocks of the second memory bank, and wherein i is greater than or equal to 1 and less than or equal to m.

14. The memory system of claim 13, wherein:
when the one first connection line is disposed between the i-th row of memory blocks of the first memory bank and the i-th row of memory blocks of the second memory bank, the one first connection line is located at a middle position between the i-th row of memory blocks of the first memory bank and the i-th row of memory blocks of the second memory bank; and
when the two first connection lines are disposed between the i-th row of memory blocks of the first memory bank and the i-th row of memory blocks of the second memory bank, one of the two first connection lines is adjacent to the i-th row of memory blocks of the first memory bank, and the other connection line is adjacent to the i-th row of memory blocks of the second memory bank.

15. The memory system of claim 12, wherein:
each of the memory banks includes m rows of memory blocks, wherein m is greater than or equal to 1; and
the two adjacent memory banks include a first memory bank and a second memory bank, wherein one or two first connection lines are disposed between an i-th row of memory blocks and an (i+1)-th row of memory blocks of the first memory bank and an i-th row of memory blocks and an (i+1)-th row of memory blocks of the second memory bank, and wherein i is greater than or equal to 1 and less than m.

16. The memory system of claim 15, wherein:
when the one first connection line is disposed between the i-th row of memory blocks and the (i+1)-th row of memory blocks of the first memory bank and the i-th row of memory blocks and the (i+1)-th row of memory blocks of the second memory bank, the one first connection line is located at a middle position between the i-th row of memory blocks and the (i+1)-th row of memory blocks of the first memory bank and the i-th row of memory blocks and the (i+1)-th row of memory blocks of the second memory bank; and
when the two first connection lines are disposed between the i-th row of memory blocks and the (i+1)-th row of memory blocks of the first memory bank and the i-th row of memory blocks and the (i+1)-th row of memory blocks of the second memory bank, one of the two first connection lines is adjacent to the i-th row of memory blocks and the (i+1)-th row of memory blocks of the first memory bank, and the other connection line is adjacent to the i-th row of memory blocks and the (i+1)-th row of memory blocks of the second memory bank.

17. The memory system of claim 12, wherein each of the memory banks includes a plurality of memory blocks, and no connection line for connecting the peripheral circuit is disposed in an area between adjacent memory blocks of a same memory bank.

18. The memory system of claim 12, wherein:
a memory block is disposed in a third area of each of the memory banks; and
a word line driver circuit and a sense amplifier circuit are disposed in a fourth area of the peripheral circuit, wherein the fourth area overlaps with the third area in the view.

19. The memory system of claim 12, wherein the memory array is bonded with the peripheral circuit.

20. A method for forming a memory, comprising:
forming a memory array including a plurality of memory banks, wherein at least one first connection line is disposed in a first area between two adjacent memory banks;
forming a peripheral circuit, wherein a memory bank row control circuit is disposed in a second area of the peripheral circuit; and
bonding the memory array with the peripheral circuit, so that the peripheral circuit and the memory array are stacked, and in a view perpendicular to a stacking direction, the second area does not overlap with the first area.
